(19) United States
(12) Patent Application Publication
(10) Pub. No.: US 2024/0167148 A1
(43) Pub. Date: May 23, 2024

(54) METHODS OF REMOVING METAL OXIDE USING CLEANING PLASMA

(71) Applicant: Applied Materials, Inc., Santa Clara, CA (US)

(72) Inventors: Tsung-Han Yang, San Jose, CA (US); Shiyu Yue, Sunnyvale, CA (US); Rongjun Wang, Dublin, CA (US)

(73) Assignee: Applied Materials, Inc., Santa Clara, CA (US)

(21) Appl. No.: 17/989,767

(22) Filed: Nov. 18, 2022

(51) Int. Cl. C23C 16/02; B08B 7/00; C23C 16/06

(52) U.S. Cl. CPC C23C 16/0227; B08B 7/0035; C23C 16/06

(57) ABSTRACT

Embodiments of the disclosure are directed to methods of removing metal oxide from a substrate surface by exposing the substrate surface to an un-biased cleaning plasma comprising a mixture of hydrogen (H₂) and oxygen (O₂). In some embodiments, the substrate surface has at least one feature thereon, the at least one feature defining a trench having a top surface, a bottom surface, and two opposed sidewalls. The un-biased cleaning plasma comprises in a range of from 1% to 20% oxygen (O₂) on a molecular basis and greater than or equal to 80% hydrogen (H₂). The un-biased cleaning plasma removes substantially all of the metal oxide—such as molybdenum oxide (MoOx), ruthenium oxide (RuOx), or tungsten oxide (WOx)—from the substrate surface, and the top surface, the bottom surface, and the two opposed sidewalls of the trench without damaging the dielectric and/or critical dimension (CD)/profile of the structure.

### TECHNICAL FIELD

Embodiments of the present disclosure pertain to methods of removing metal oxide from a substrate surface. In particular, embodiments of the disclosure are directed to methods of removing metal oxide using an un-biased cleaning plasma.

### BACKGROUND

Integrated circuits are made possible by processes which produce patterned material layers on a substrate. Producing patterned material on a substrate requires controlled methods for removal of exposed material. Chemical etching is used for a variety of purposes, including transferring a pattern in photoresist into underlying layers, thinning layers, or thinning lateral dimensions of features already present on the surface. Sometimes it is necessary to have an etch process that etches one material faster than another facilitating, for example, a pattern transfer process.

Incoming substrates often have residue on them from previous processing, from native oxide formation on a metal, and etch residue from via/trench hole formation. To improve process performance of a metal fill, e.g., low line resistance, high yield, and high reliability, any residue and/or native oxide must be removed. Remote plasma and direct plasma, alone, are incapable of removing the residue and native oxide inside the structure effectively. Remote plasma radicals do not reach the structure trench well due to its lifetime, and direct plasma does not clear the sidewalls of a structure due to the directionality.

Native oxide, such as tungsten oxide (WOx), forms as a result of etching a via/trench and vacuum break. Thus, a pre-clean process is required to clean the native oxide, such as tungsten oxide (WOx) to minimize resistive capacitance (“resistivity” or “resistance”) in the integrated circuit. Resistivity is an intrinsic property of a material and a measurement of a material's resistance to the movement of charge through the material. The resistivity of a material affects the electrical operation of an integrated circuit.

Current pre-clean processes involve exposing the substrate to a plasma of argon (Ar) and hydrogen (H₂) to remove the native oxide. These preclean processes are performed in the presence of an external bias at the substrate surface, which may damage the dielectric and critical dimension (CD)/profile of the structure.

Therefore, there is a need in the art for improved processes for etching (cleaning) materials and structures on semiconductor substrates without damaging the dielectric and/or critical dimension (CD)/profile of the structure.

### SUMMARY

One or more embodiments are directed to a method of removing a metal oxide from a substrate surface. The method comprises exposing the substrate surface to an un-biased cleaning plasma comprising a mixture of hydrogen (H₂) and oxygen (O₂) to remove the metal oxide to form a clean metal surface. The un-biased cleaning plasma comprises in a range of from 1% to 20% oxygen (O₂) on a molecular basis.

Additional embodiments are directed to a processing method comprising exposing a substrate surface having at least one feature thereon to a preclean process. The at least one feature defines a trench having a top surface, a bottom surface, and two opposed sidewalls. Each of the top surface, the bottom surface, and the two opposed sidewalls have metal oxide thereon. The preclean process comprises exposing the top surface, the bottom surface, and the two opposed sidewalls to an un-biased cleaning plasma consisting essentially of a mixture of hydrogen (H₂) and in a range of from 1% to 20% oxygen (O₂), on a molecular basis, to remove the metal oxide to form a clean metal surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments of the disclosure;

FIG. 2 illustrates a process flow diagram of a processing method according to one or more embodiments of the disclosure;

FIG. 3A illustrates a schematic cross-sectional view of a feature on a substrate according to one or more embodiments of the disclosure;

FIG. 3B illustrates a schematic cross-sectional view of the feature shown in FIG. 3A having a clean metal surface after exposure to an un-biased cleaning plasma according to one or more embodiments of the disclosure;

FIG. 3C illustrates a schematic cross-sectional view of a metal film formed on the clean metal surface shown in FIG. 3B according to one or more embodiments of the disclosure; and

FIG. 3D illustrates a schematic cross-sectional view of a metal film filling the feature shown in FIG. 3B according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, or thereon, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top surface, two opposed sidewalls and a bottom surface, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which can be the same as or different from the sidewall material.

The term “on” indicates that there is direct contact between elements. The term “directly on” indicates that there is direct contact between elements with no intervening elements.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, a film is conformally deposited on a surface. As used herein, the term “conformal”, or “conformally”, refers to a film that adheres to and uniformly covers exposed surfaces with a thickness having a variation of less than 5%, less than 2%, or less than 1% relative to the average thickness of the film. For example, a 1,000 Å thick film may have less than a 10 Å variation in thickness. This thickness and variation include at least edges, corners, sides, and the bottom of recesses. For example, a conformal film deposited by ALD in various embodiments of the disclosure would provide coverage over the deposited region of essentially uniform thickness on complex surfaces.

Embodiments of the disclosure advantageously provide methods of removing a metal oxide from a substrate surface without the presence of an external bias at the substrate surface. Advantageously, the disclosure provides processes for etching (cleaning) materials and structures on semiconductor substrates without damaging the dielectric and/or critical dimension (CD)/profile of the structure.

The inventors have surprisingly found that using an un-biased cleaning plasma comprising a mixture of hydrogen (H₂) and oxygen (O₂) removes the metal oxide from the substrate surface without the presence of an external bias at the substrate surface. Advantageously, the un-biased cleaning plasma comprising a mixture of hydrogen (H₂) and oxygen (O₂) removes all, or substantially all of the metal oxide from the substrate surface without the presence of an external bias at the substrate surface.

In some embodiments, when the un-biased cleaning plasma comprises in a range of from 1% to 20% oxygen (O₂) on a molecular basis and greater than or equal to 80% hydrogen (H₂), a chemical vapor transport (CVT) type reaction is observed. In chemical vapor transport reactions, the deposited solid is non-volatile. For example, the non-volatile deposited compound may be a metal oxide, such as molybdenum oxide (MoOx), ruthenium oxide (RuOx), or tungsten oxide (WOx). Non-volatile solids, such as molybdenum oxide (MoOx), ruthenium oxide (RuOx), or tungsten oxide (WOx), are volatilized in presence of a reactant, such as the mixture of hydrogen (H₂) and oxygen (O₂) described herein. The mixture of hydrogen (H₂) and oxygen (O₂) reacts with the metal oxide, such as molybdenum oxide (MoOx), ruthenium oxide (RuOx), or tungsten oxide (WOx). The compound formed from the reaction of the mixture of hydrogen (H₂) and oxygen (O₂) with the metal oxide, such as molybdenum oxide (MoOx), ruthenium oxide (RuOx), or tungsten oxide (WOx), is volatilized as a metal, such as molybdenum (Mo), ruthenium (Ru), or tungsten (W). Then, the volatized metal material, such as molybdenum (Mo), ruthenium (Ru), or tungsten (W), can be transported in gaseous form and deposited on a substrate as a metal film or as a crystal.

Further embodiments of the disclosure are described by way of the Figures, which illustrate substrate surfaces, a feature formed on a substrate surface, and processes for removing a metal oxide from the substrate surface and the surfaces of the feature in accordance with one or more embodiments of the disclosure. The processes shown are merely illustrative possible uses for the disclosed processes, and the skilled artisan will recognize that the disclosed processes are not limited to the illustrated applications.

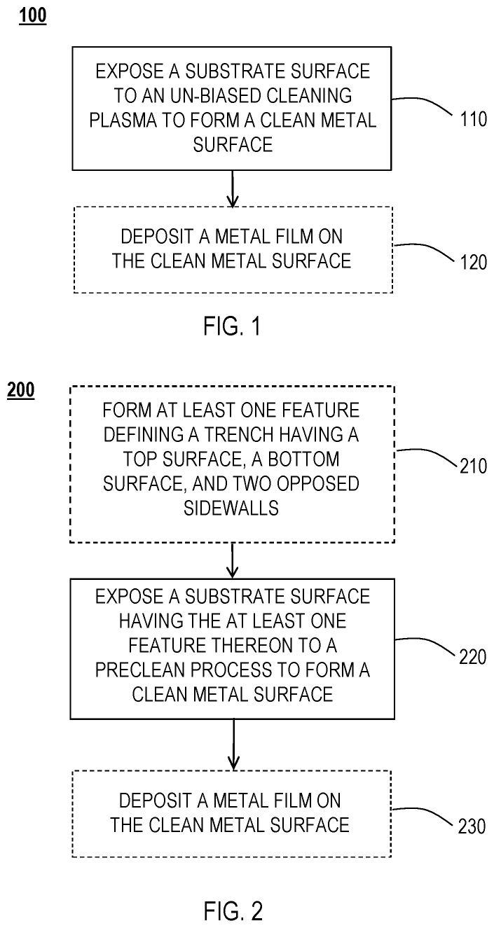

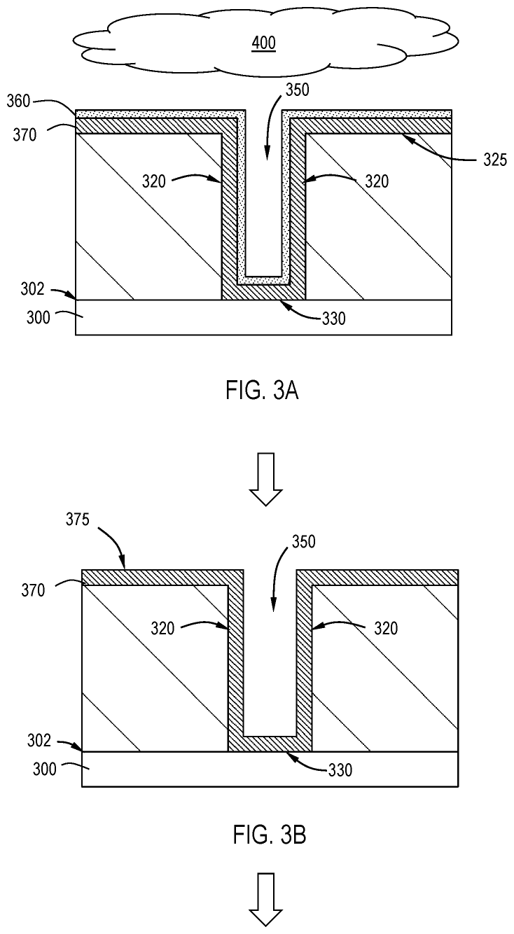

FIG. 1 illustrates a process flow diagram of a method 100 according to one or more embodiments. FIG. 2 illustrates a process flow diagram of a processing method 200 according to one or more embodiments.

The method 100, at operation 110, comprises exposing a substrate surface to an un-biased cleaning plasma to form a clean metal surface. In some embodiments, the method 100 consists essentially of exposing the substrate surface to an un-biased cleaning plasma comprising a mixture of hydrogen (H₂) and oxygen (O₂) to remove the metal oxide to form the clean metal surface. In other embodiments, the method 100 consists of exposing the substrate surface to an un-biased cleaning plasma comprising a mixture of hydrogen (H₂) and oxygen (O₂) to remove the metal oxide to form the clean metal surface.

In some embodiments, the un-biased cleaning plasma comprises a mixture of hydrogen (H₂) and oxygen (O₂). In some embodiments, the un-biased cleaning plasma comprises a mixture of hydrogen (H*) radicals and oxygen (O*) radicals. In some embodiments, the un-biased cleaning plasma comprises a mixture of hydrogen (H⁺) ions and oxygen (O⁻²) ions. In some embodiments, the un-biased cleaning plasma comprises one or more of hydrogen (H₂)/hydrogen (H*) radicals/hydrogen (H⁺) ions and oxygen (O₂)/oxygen (O*) radicals/oxygen (O⁻²) ions, and any combination thereof. In some embodiments, the un-biased cleaning plasma comprises in a range of from 1% to 20% oxygen (O₂) on a molecular basis. In some embodiments, the mixture of hydrogen (H₂) and oxygen (O₂) comprises greater than or equal to 80% hydrogen (H₂). In other embodiments, the mixture of hydrogen (H₂) and oxygen (O₂) comprises greater than or equal to 90% hydrogen (H₂).

The un-biased cleaning plasma may be generated by any suitable plasma source known to the skilled artisan. In some embodiments, the un-biased cleaning plasma is generated by a plasma source selected from one or more of a capacitively coupled plasma (CCP) source, an inductively coupled plasma (ICP) source, a microwave plasma source, or a remote plasma source.

Remote plasma and direct plasma, alone, are incapable of removing the residue and native oxide inside the structure effectively. Remote plasma radicals do not reach the structure trench well due to its lifetime, and direct plasma does not clear the sidewalls of a structure due to the directionality.

Advantageously, when the un-biased cleaning plasma comprises in a range of from 1% to 20% oxygen (O₂) on a molecular basis and greater than or equal to 80% hydrogen (H₂), a chemical vapor transport (CVT) type reaction is observed and the volatized metal material, such as molybdenum (Mo), ruthenium (Ru), or tungsten (W), can be transported in gaseous form and deposited on a substrate as a metal film or as a crystal.

In some embodiments, the substrate surface is maintained at a temperature of greater than or equal to 300° C. In some embodiments, the substrate surface is maintained at a temperature in a range of 300° C. to 750° C., including all values and subranges therebetween. The substrate surface may be maintained at a temperature in a range of 300° C. to 750° C., including all values and subranges therebetween, and exposing the substrate surface to the un-biased cleaning plasma comprising a mixture of hydrogen (H₂) and oxygen (O₂) having greater than or equal to 80% hydrogen (H₂), or greater than or equal to 90% hydrogen (H₂), advantageously forms a clean metal surface. For example, in some embodiments, when the mixture of hydrogen (H₂) and oxygen (O₂) comprises greater than or equal to 90% hydrogen (H₂), the substrate surface may be maintained at a temperature in a range of 300° C. to less than or equal to 500° C. In some embodiments, the mixture of hydrogen (H₂) and oxygen (O₂) comprises greater than or equal to 80% hydrogen (H₂), the substrate surface may be maintained at a temperature in a range of greater than or equal to 500° C. to 750° C.

In some embodiments, the method 100 is performed at a pressure of less than or equal to 50 mTorr, including less than or equal to 40 mTorr, less than or equal to 30 mTorr, or less than or equal to 20 mTorr. In some embodiments, the method 100 is performed at a pressure of greater than or equal to 50 mTorr. In some embodiments, the method 100 is performed at a pressure in a range of from greater than or equal to 50 mTorr to less than or equal to 5 Torr, including all values and subranges therebetween.

The un-biased cleaning plasma advantageously removes substantially all of the metal oxide from the substrate surface. As used in this regard, “substantially all of the metal oxide” means that less than about 5%, including less than about 4%, less than about 3%, less than about 2%, less than about 1%, less than about 0.5%, and less than about 0.1% of the total composition of the metal oxide on the substrate surface remains after exposing the substrate surface to the un-biased cleaning plasma.

In some embodiments, the method 100 advantageously comprises a single exposure of the substrate surface to the un-biased cleaning plasma to remove all, or substantially all of the metal oxide from the substrate surface without the presence of an external bias at the substrate surface.

At operation 120, the method 100 optionally comprises depositing a metal film on the clean metal surface. The metal film may include any metal known to the skilled artisan. In some embodiments, the metal film comprises a transition metal. In some embodiments, the metal film comprises one or more of molybdenum (Mo), ruthenium (Ru), or tungsten (W), or alloys thereof. In some embodiments, depositing the metal film on the clean metal surface comprises one or more of atomic layer deposition (ALD), chemical vapor deposition (CVD), or pulsed CVD (pCVD). In some embodiments, the substrate surface is exposed to a first precursor and a second precursor simultaneously. In some embodiments, the substrate surface is exposed to the first precursor and the second precursor sequentially.

In some embodiments, depositing the metal film comprises atomic layer deposition (ALD), which includes one or more cycles of exposing the substrate surface to a first precursor, a purge gas, a second precursor, and the purge gas.

In some embodiments, depositing the metal film comprises a spatial ALD process, wherein a first reactive gas and second reactive gas are delivered simultaneously to the reaction zone but are separated by an inert gas curtain and/or a vacuum curtain. In some embodiments, depositing the metal film comprises co-flowing the first reactive gas and the second reactive gas. In some embodiments, depositing the metal film comprises chemical vapor deposition (CVD). In some embodiments, depositing the metal film comprises pulsed chemical vapor deposition (pCVD), wherein one or both of the reactants is/are pulsed into a processing chamber.

In some embodiments, the method 100 consists essentially of exposing the substrate surface to an un-biased cleaning plasma comprising a mixture of hydrogen (H₂) and oxygen (O₂) to remove the metal oxide to form the clean metal surface (operation 110) and depositing a metal film on the clean metal surface (operation 120). In other embodiments, the method 100 consists of exposing the substrate surface to an un-biased cleaning plasma comprising a mixture of hydrogen (H₂) and oxygen (O₂) to remove the metal oxide to form the clean metal surface (operation 110) and depositing a metal film on the clean metal surface (operation 120).

Some embodiments are directed to processing methods for removing a metal oxide from a bottom surface in a feature formed on a substrate surface. The processing method 200, at operation 210, optionally comprises forming at least one feature on a substrate surface. The at least one feature can be formed by any process known to the skilled artisan. In some embodiments, the at least one feature defines a trench having a top surface, a bottom surface, and two opposed sidewalls, each of the top surface, the bottom surface, and the two opposed sidewalls having metal oxide thereon.

In some embodiments, the processing method 200, at operation 220, comprises exposing the substrate surface having the at least one feature thereon to a preclean process. In some embodiments, the preclean process comprises exposing the top surface, the bottom surface, and the two opposed sidewalls to an un-biased cleaning plasma consisting essentially of a mixture of hydrogen (H₂) and in a range of from 1% to 20% oxygen (O₂), on a molecular basis, to remove the metal oxide to form a clean metal surface. In some embodiments, the mixture of hydrogen (H₂) and oxygen (O₂) comprises greater than or equal to 80% hydrogen (H₂). In other embodiments, the mixture of hydrogen (H₂) and oxygen (O₂) comprises greater than or equal to 90% hydrogen (H₂).

In some embodiments, the substrate surface is maintained at a temperature of greater than or equal to 300° C. In some embodiments, the substrate surface is maintained at a temperature in a range of 300° C. to 750° C., including all values and subranges therebetween. The substrate surface may be maintained at a temperature in a range of 300° C. to 750° C., including all values and subranges therebetween, and exposing the substrate surface to the un-biased cleaning plasma comprising a mixture of hydrogen (H₂) and oxygen (O₂) having greater than or equal to 80% hydrogen (H₂), or greater than or equal to 90% hydrogen (H₂), advantageously forms a clean metal surface. For example, in some embodiments, when the mixture of hydrogen (H₂) and oxygen (O₂) comprises greater than or equal to 90% hydrogen (H₂), the substrate surface may be maintained at a temperature in a range of 300° C. to less than or equal to 500° C. In some embodiments, the mixture of hydrogen (H₂) and oxygen (O₂) comprises greater than or equal to 80% hydrogen (H₂), the substrate surface may be maintained at a temperature in a range of greater than or equal to 500° C. to 750° C.

In some embodiments, the processing method 200 is performed at a pressure of less than or equal to 50 mTorr, including less than or equal to 40 mTorr, less than or equal to 30 mTorr, or less than or equal to 20 mTorr. In some embodiments, the processing method 200 is performed at a pressure of greater than or equal to 50 mTorr. In some embodiments, the processing method 200 is performed at a pressure in a range of from greater than or equal to 50 mTorr to less than or equal to 5 Torr, including all values and subranges therebetween.

The un-biased cleaning plasma advantageously removes substantially all of the metal oxide from the substrate surface. As used in this regard, “substantially all of the metal oxide” means that less than about 5%, including less than about 4%, less than about 3%, less than about 2%, less than about 1%, less than about 0.5%, and less than about 0.1% of the total composition of the metal oxide on the substrate surface remains after exposing the substrate surface to the un-biased cleaning plasma.

In some embodiments, the method 200 advantageously comprises a single exposure of the substrate surface to the pre-clean process to remove all, or substantially all of the metal oxide from the substrate surface without the presence of an external bias at the substrate surface.

In some embodiments, the processing method 200, at operation 230, optionally comprises depositing a metal film on the clean metal surface. The metal film may include any metal known to the skilled artisan. In some embodiments, the metal film comprises a transition metal. In some embodiments, the metal film comprises one or more of molybdenum (Mo), ruthenium (Ru), or tungsten (W), or alloys thereof. In some embodiments, depositing the metal film on the clean metal surface comprises one or more of atomic layer deposition (ALD), chemical vapor deposition (CVD), or pulsed CVD (pCVD). In some embodiments, the substrate surface is exposed to a first precursor and a second precursor simultaneously. In some embodiments, the substrate surface is exposed to the first precursor and the second precursor sequentially.

In some embodiments, the processing method 200 consists essentially of forming at least one feature comprising a top surface, a bottom surface, and two opposed sidewalls (operation 210), each of the top surface, the bottom surface, and the two opposed sidewalls having metal oxide thereon, exposing a substrate surface having the at least one feature thereon to a preclean process to form a clean metal surface (operation 220), and depositing a metal film on the clean metal surface (operation 230). In some embodiments, the metal film is deposited on the clean metal surface (operation 230) to fill the at least one feature.

In some embodiments, the processing method 200 consists of forming at least one feature comprising a top surface, a bottom surface, and two opposed sidewalls (operation 210), each of the top surface, the bottom surface, and the two opposed sidewalls having metal oxide thereon, exposing a substrate surface having the at least one feature thereon to a preclean process to form a clean metal surface (operation 220), and depositing a metal film on the clean metal surface (operation 230). In some embodiments, the metal film is deposited on the clean metal surface (operation 230) to fill the at least one feature.

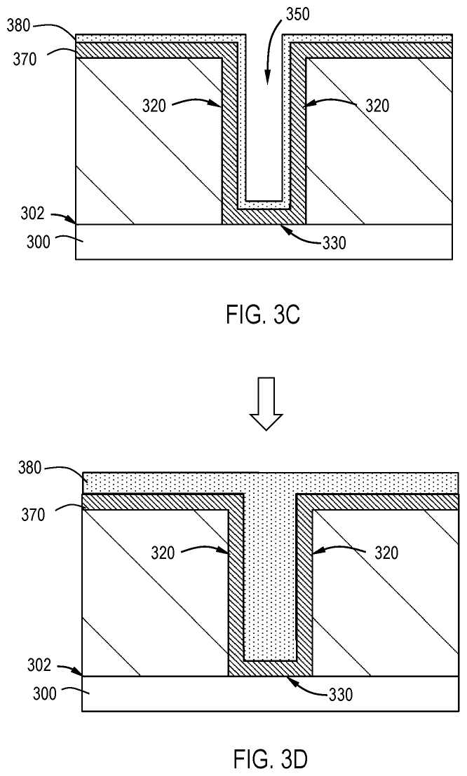

FIGS. 3A-3D illustrate cross-sectional views of processing method 200 as shown in FIG. 2, according to one or more embodiments of the disclosure. FIG. 3A illustrates a schematic cross-sectional view of a feature on a substrate. FIG. 3B illustrates a schematic cross-sectional view of the feature shown in FIG. 3A having a clean metal surface after exposure to the un-biased cleaning plasma described herein. FIG. 3C illustrates a schematic cross-sectional view of a metal film formed on the clean metal surface shown in FIG. 3B. FIG. 3D illustrates a schematic cross-sectional view of a metal film filling the feature shown in FIG. 3B.

Referring first to FIG. 3A, a substrate 300 is shown, having a surface such as top surface 302 and at least one feature 350 formed thereon. The Figures show a substrate 300 having a single feature 350 for illustrative purposes; however, those skilled in the art will understand that there can be more than one feature 350.

The shape of the feature 350 can be any suitable shape including, but not limited to, trenches and cylindrical vias. As used in this regard, the term “feature” means any intentional surface irregularity. Suitable examples of features include, but are not limited to, trenches which have a top surface, two opposed sidewalls and a bottom surface, peaks which have a top and two sidewalls extending upward from a surface, such as a substrate surface 302, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which may be different material. In one or more embodiments, the at least one feature 350 comprises one or more of a trench or a via. In specific embodiments, the at least one feature 350 comprises a trench. In still further embodiments, the term “at least one feature 350” and “trench 350” may be used interchangeably.

The trench 350 comprises a top surface 325, a bottom surface 330 and two opposed sidewalls 320. The trench 350 has a depth to the bottom surface 330 and a width between the two opposed sidewalls 320. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In some embodiments, the trench 350 has an aspect ratio (depth/width) in a range of 1:1 to 20:1, 3:1 to 20:1, 3:1 to 15:1, 5:1 to 20:1, 10:1 to 20:1, or 15:1 to 20:1.

The substrate 300 can be any suitable substrate material. In one or more embodiments, the substrate 300 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. Although a few examples of materials from which the substrate 300 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the two opposed sidewalls 320 include any suitable dielectric material known to the skilled artisan. In some embodiments, the dielectric material comprises a low-K dielectric material including, but not limited to, silicon oxide (SiOx), silicon sub-oxides, silicon nitride (SiNₓ), silicon nitride (Si₃N₄), silicon oxynitride (SiOₓN_{y}), or combinations thereof.

In some embodiments, the underlying material at the bottom surface 330 of the trench 350 may be a conductor such as a metal (e.g., copper), which can be the same as or different from the sidewall material. In some embodiments, the bottom surface 330 comprises the same material as the two opposed sidewalls 320.

FIG. 3A illustrates a native oxide layer 360 (a metal oxide layer 360), that is present on the top surface 325 of the trench 350, along the two opposed sidewalls 320, and on the bottom surface 330. Without intending to be bound by theory, it is thought that as a result of as a result of etching a via/trench, an increased amount of metal oxide forms on the bottom surface 330 compared to the top surface 325 or along the two opposed sidewalls 320. In some embodiments, the native oxide layer 360 comprises one or more of molybdenum oxide (MoOx), ruthenium oxide (RuOx), or tungsten oxide (WOx). In some embodiments, the native oxide layer 360 is on top of a first metal film 370. In some embodiments, the first metal film 370 is conformally deposited directly on the top surface 325, along the two opposed sidewalls 320, and on the bottom surface 330. In some embodiments, the native oxide layer 360 is directly on the first metal film 370.

The first metal film 370 can include any suitable metal known to the skilled artisan. In some embodiments, the first metal film 370 comprises one or more of molybdenum (Mo), ruthenium (Ru), or tungsten (W).

FIG. 3A illustrates exposing the top surface 325, the two opposed sidewalls 320, and the bottom surface 330 to an un-biased cleaning plasma 400 consisting essentially of a mixture of hydrogen (H₂) and in a range of from 1% to 20% oxygen (O₂), on a molecular basis, to remove the metal oxide layer 360 to form a clean metal surface (shown in FIG. 3B).

Remote plasma and direct plasma, alone, are incapable of removing the residue and native oxide (such as native oxide layer 360) inside the structure, such as the at least one feature 350, effectively. Remote plasma radicals do not reach the structure trench, such as the least one feature 350, well due to its lifetime, and direct plasma does not clear the sidewalls, such as the two opposed sidewalls 320, of a structure due to the directionality.

Current pre-clean processes involve exposing the substrate to a plasma of argon (Ar) and hydrogen (H₂) to remove the native oxide. These preclean processes are performed in the presence of an external bias at the substrate surface, which may damage the dielectric and critical dimension (CD)/profile of the structure.

The inventors have surprisingly found that using an un-biased cleaning plasma comprising a mixture of hydrogen (H₂) and oxygen (O₂) removes the metal oxide from the substrate surface without the presence of an external bias at the substrate surface.

Advantageously, the unbiased cleaning plasma (illustrated by the cloud 400 in FIG. 3A) removes the metal oxide layer 360 from the top surface 325 of the at least one feature 350, the two opposed sidewalls 320, and the bottom surface 330 without damaging the two opposed sidewalls 320 and/or critical dimension (CD)/profile of the at least one feature 350.

The un-biased cleaning plasma 400 advantageously removes all of the metal oxide layer 360 from the top surface 325, the two opposed sidewalls 320, and the bottom surface 330. In some embodiments, the un-biased cleaning plasma 400 removes substantially all of the metal oxide layer 360 from the top surface 325, the two opposed sidewalls 320, and the bottom surface 330. As used in this regard, “substantially all of the metal oxide layer 360” means that less than about 5%, including less than about 4%, less than about 3%, less than about 2%, less than about 1%, less than about 0.5%, and less than about 0.1% of the total composition of the metal oxide layer 360 remains on any of the surfaces of the trench 350 after exposing the top surface 325, the two opposed sidewalls 320, and the bottom surface 330 to the un-biased cleaning plasma 400.

FIG. 3B illustrates the clean metal surface 375 formed by exposing the top surface 325, the two opposed sidewalls 320, and the bottom surface 330 to the un-biased cleaning plasma 400 consisting essentially of a mixture of hydrogen (H₂) and in a range of from 1% to 20% oxygen (O₂), on a molecular basis, to remove the metal oxide layer 360. As used in this manner, the term “consists essentially of” means that the un-biased cleaning plasma 400 comprises greater than or equal to about 95%, 98%, 99% or 99.9% of the stated mixture. In some embodiments, the mixture of hydrogen (H₂) and oxygen (O₂) comprises greater than or equal to 80% hydrogen (H₂). In other embodiments, the mixture of hydrogen (H₂) and oxygen (O₂) comprises greater than or equal to 90% hydrogen (H₂). In some embodiments, the un-biased cleaning plasma 400 consists of a mixture of hydrogen (H₂) and in a range of from 1% to 20% oxygen (O₂), on a molecular basis. As used in this manner, the term “consists of” means that the un-biased cleaning plasma 400 excludes additional elements and/or components from the stated mixture.

FIG. 3C illustrates a schematic cross-sectional view of a metal film (e.g., a second metal film 380) formed on the clean metal surface 375 shown in FIG. 3B. In some embodiments, the first metal film 370 and the second metal film 380 have the same composition. In other embodiments, the first metal film 370 and the second metal film 380 are different. In some embodiments, the first metal film 370 and/or the second metal film 380 comprises molybdenum (Mo), ruthenium (Ru), and/or tungsten (W), or alloys thereof. In some embodiments, the second metal film 380 is formed on the clean metal surface 375 by atomic layer deposition (ALD), chemical vapor deposition (CVD), or pulsed CVD (pCVD).

Further aspects of the disclosure pertain to a method that is part of a gap fill process. In some embodiments, the second metal film 380 is deposited on one or more high aspect ratio gap features, including vertical gap features and/or horizontal gap features, and the second metal film 380 in the gap features forms horizontal interconnects through which current flows. Without intending to be bound by theory, gaps filled with the second metal film 380 conformally deposited on the clean metal surface 375 that has been exposed to the un-biased cleaning plasma 400, according to one or more embodiments of the methods described herein, result in improved electrical operation of an integrated circuit, by minimizing power losses and overheating in the integrated circuit.

Referring to FIG. 3D, the second metal film 380 is conformally deposited on the clean metal surface 375 to fill the feature 350. In some embodiments, the second metal film 380 is conformally deposited on the clean metal surface 375 by one or more of atomic layer deposition (ALD), chemical vapor deposition (CVD), or pulsed CVD (pCVD) to a desired thickness fill the feature 350.

In some embodiments, the second metal film 380 is laterally bounded by the two opposed sidewalls 320 of the trench 350. As used in this regard, “laterally bounded” means that the deposited material does not extend beyond the point of intersection between the top surface and the two opposed sidewalls 320. In some embodiments, the second metal film 380 extends above the trench 350. In some embodiments, the second metal film 380 fills the trench 350. As used in this regard, a film which “fills the trench 350” has a volume which occupies at least 95%, at least 98%, or at least 99% of the volume of the trench 350. In some embodiments, the second metal film which fills the trench 350 has a fill height in a range of from 30 nm to 75 nm, including in a range of from 40 nm to 60 nm.

Embodiments of the disclosure advantageously provides metal film (e.g., the second metal film 380) that are free or substantially free of voids and seams. As used in this regard, “substantially free” means that less than about 5%, including less than about 4%, less than about 3%, less than about 2%, less than about 1%, less than about 0.5%, and less than about 0.1% of the total composition of the conformally deposited metal film (e.g., the second metal film 380), on an atomic basis, comprises voids and/or seams.

The methods described herein may be performed in any suitable processing chamber known to the skilled artisan. The processing chamber may be a SiCoNi™ Preclean chamber available from Applied Materials of Santa Clara, Calif. The processing chamber may be a Selectra™ Etch chamber available from Applied Materials of Santa Clara, Calif. The methods described herein may be performed in, for example, an atomic layer deposition (ALD) processing chamber (including a spatial ALD processing chamber), a chemical vapor deposition (CVD) processing chamber, or a pulsed CVD (pCVD) processing chamber.

In some embodiments, the operations of the methods described herein are each performed within the same processing chamber or within the same processing system. In some embodiments, the operations of the methods described herein are each performed within a different processing chamber. In some embodiments, the different processing chambers are connected as part of a processing system. In some embodiments, the operations of the methods described herein are each performed within a different processing chamber, and each different processing chamber is part of a separate processing system. In some embodiments, the operations of the methods described herein are performed without an intervening vacuum break.

In some embodiments, one or more of the operations of the methods described herein is performed in situ without breaking vacuum. In some embodiments, one or more of the operations of the methods described herein is performed ex situ. As used herein, the term “in situ” refers to operations of the methods described herein that are each performed in the same processing chamber or a different processing chamber that is connected as part of a processing system, such that each of the operations of the methods described herein are performed without an intervening vacuum break. As used herein, the term “ex situ” refers to operations of the methods described herein that are each performed in the same processing chamber or a different processing chamber such that one or more of the operations of the methods described herein are performed with an intervening vacuum break.

One or more embodiments of the disclosure are directed to a non-transitory computer readable medium including instructions, that, when executed by a controller of a processing chamber, cause the processing chamber to perform the methods described herein, e.g., methods 100 and 200. In some embodiments, the non-transitory computer readable medium includes instructions, that, when executed by a controller of a processing chamber, cause the processing chamber to: expose the substrate surface to an un-biased cleaning plasma comprising a mixture of hydrogen (H₂) and oxygen (O₂) to remove the metal oxide to form a clean metal surface, the un-biased cleaning plasma comprising in a range of from 1% to 20% oxygen (O₂) on a molecular basis. In some embodiments, the non-transitory computer readable medium includes instructions, that, when executed by a controller of a processing chamber, cause the processing chamber to: deposit a metal film on the clean metal surface.

In some embodiments, the non-transitory computer readable medium includes instructions, that, when executed by a controller of a processing chamber, cause the processing chamber to: expose a substrate surface having at least one feature thereon to a preclean process, the at least one feature defining a trench having a top surface, a bottom surface, and two opposed sidewalls, each of the top surface, the bottom surface, and the two opposed sidewalls having metal oxide thereon, the preclean process comprises exposing the top surface, the bottom surface, and the two opposed sidewalls to an un-biased cleaning plasma consisting essentially of a mixture of hydrogen (H₂) and in a range of from 1% to 20% oxygen (O₂), on a molecular basis, to remove the metal oxide to form a clean metal surface. In some embodiments, the non-transitory computer readable medium includes instructions, that, when executed by a controller of a processing chamber, cause the processing chamber to: deposit a metal film on the clean metal surface. In some embodiments, the non-transitory computer readable medium includes instructions, that, when executed by a controller of a processing chamber, cause the processing chamber to: conformally deposit a metal film on the clean metal surface to fill the trench.

Reference throughout this specification to “one embodiment,” “certain embodiments,” “one or more embodiments” or “an embodiment” means that a particular feature, structure, material, or characteristic described in connection with the embodiment is included in at least the embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of removing a metal oxide from a substrate surface, the method comprising:
exposing the substrate surface to an un-biased cleaning plasma comprising a mixture of hydrogen (H₂) and oxygen (O₂) to remove the metal oxide to form a clean metal surface, the un-biased cleaning plasma comprising in a range of from 1% to 20% oxygen (O₂) on a molecular basis.

2. The method of claim 1, wherein the mixture of hydrogen (H₂) and oxygen (O₂) comprises greater than or equal to 80% hydrogen (H₂).

3. The method of claim 1, wherein the mixture of hydrogen (H₂) and oxygen (O₂) comprises greater than or equal to 90% hydrogen (H₂).

4. The method of claim 1, wherein the un-biased cleaning plasma removes substantially all of the metal oxide from the substrate surface.

5. The method of claim 1, wherein the metal oxide comprises one or more of molybdenum oxide (MoOx), ruthenium oxide (RuOx), or tungsten oxide (WOx).

6. The method of claim 5, wherein the metal oxide comprises tungsten oxide (WOx).

7. The method of claim 1, wherein the un-biased cleaning plasma comprises one or more of an inductively coupled plasma (ICP) or a capacitively coupled plasma (CCP).

8. The method of claim 1, wherein the substrate surface is maintained at a temperature in a range of 300° C. to 750° C.

9. The method of claim 1, wherein the method is performed at a pressure of greater than or equal to 50 mTorr.

10. The method of claim 1, further comprising depositing a metal film on the clean metal surface.

11. A processing method comprising:
exposing a substrate surface having at least one feature thereon to a preclean process, the at least one feature defining a via having a top surface, a bottom surface, and two opposed sidewalls, each of the top surface, the bottom surface, and the two opposed sidewalls having metal oxide thereon, the preclean process comprises exposing the top surface, the bottom surface, and the two opposed sidewalls to an un-biased cleaning plasma consisting essentially of a mixture of hydrogen (H₂) and in a range of from 1% to 20% oxygen (O₂), on a molecular basis, to remove the metal oxide to form a clean metal surface.

12. The processing method of claim 11, wherein the at least one feature has an aspect ratio in a range of from 3:1 to 15:1.

13. The processing method of claim 11, wherein the mixture of hydrogen (H₂) and oxygen (O₂) comprises greater than or equal to 90% hydrogen (H₂).

14. The processing method of claim 11, wherein the un-biased cleaning plasma removes substantially all of the metal oxide from the top surface, the bottom surface, and the two opposed sidewalls.

15. The processing method of claim 11, wherein the metal oxide comprises one or more of molybdenum oxide (MoOx), ruthenium oxide (RuOx), or tungsten oxide (WOx).

16. The processing method of claim 15, wherein the metal oxide comprises tungsten oxide (WOx).

17. The processing method of claim 11, wherein the un-biased cleaning plasma comprises one or more of an inductively coupled plasma (ICP) or a capacitively coupled plasma (CCP).

18. The processing method of claim 11, wherein the substrate surface is maintained at a temperature in a range of 300° C. to 750° C.

19. The processing method of claim 11, wherein the method is performed at a pressure of greater than or equal to 50 mTorr.

20. The processing method of claim 11, further comprising depositing a metal film on the clean metal surface.
